(19) United States
(12) Patent Application Publication
(10) Pub. No.: US 2017/0105293 A1
(43) Pub. Date: Apr. 13, 2017

(54) DISPLAY DEVICE

(71) Applicant: ABLETECH CO., LTD., Paju-si (KR)

(72) Inventor: Yong Min KIM, Jeonjusi (KR)

(21) Appl. No.: 14/886,715

(22) Filed: Oct. 19, 2015

(30) Foreign Application Priority Data
Oct. 8, 2015 (KR) 10-2015-0141273

(51) Int. Cl. H05K 5/00; H05K 5/02

(52) U.S. Cl. CPC H05K 5/0017; H05K 5/0221; H05K 5/0217; H05K 5/023; H05K 5/0021

(57) ABSTRACT

Provided is a display device including an image panel on which a plurality of light emitting elements are arranged in a planar shape, a control module connected to the image panel and supplying a control signal and a power to the image panel, and a base frame portion on one side of which the image panel is detachably disposed and on another side of which the control module is detachably disposed.

### CROSS-REFERENCE TO RELATED APPLICATION(S)

This application claims priority to Korea Patent Application No. 10-2015-0141273, filed Oct. 8, 2015; the content of which is incorporated by reference in its entirety.

### FIELD OF THE INVENTION

The present invention relate to a display device.

### DESCRIPTION OF THE RELATED ART

In general, a display device refers to a device that is installed in an indoor exhibition center, a performance stage, etc., to represent a variety of information and deliver the information to viewers using an image. To display and transfer the image on a large screen, the display device connects and thereby utilizes a plurality of display units.

The display device according to the related art has connected and utilized display units using, for example, a cathode ray tube (CRT) and a liquid crystal display (LCD). However, in the recent times, the display device generally connects and utilizes display units to which a light emitting diode (LED) module is mounted. Such display devices are increasingly being used as devices for delivering information visually in a variety of fields, such as a broadcast program, a big stage, a big event, a concert, a brand presentation, etc, for example.

Also, the display device may be employed for a fixed installation such as an indoor/outdoor electronic sign. However, the display device has been generally employed for a rental that requires repeating installation and de-installation as a large screen with a preset size and shape, based on a necessity in a performance stage, and an event, etc.

In the related art, the plurality of unit displays is coupled to a frame that forms a framework of the display device. However, due to the weight and volume of display units, an amount of time used for installation and de-installation of the display device increases. Accordingly, there is a need to outperform the above issue.

The related art of the present disclosure is disclosed in Korean Patent Laid-Open Publication No. 10-2013-0117429, titled “Mesh type LED display,” published on Oct. 28, 2013.

### SUMMARY OF THE INVENTION

According to an aspect, there is provided a display device including an image panel on which a plurality of light emitting elements are arranged in a planar shape, a control module connected to the image panel and configured to supply a control signal and a power to the image panel, and a base frame portion on one side of which the image panel is detachably disposed and on another side of which the control module is detachably disposed.

The image panel may be provided in a quadrilateral shape and be coupled to the base frame portion through a magnetic force.

The base frame portion may include a base body configured to form a frame in a quadrilateral shape, a detachable mounting portion provided inside the base body, and to enable detachment of the control module, and an inner connecting portion configured to connect the detachable mounting portion to the base body, and to fasten the detachable mounting portion inside the base body.

The display device may further include a touring frame coupled to the base frame portion and including a supporting shape over which a hand or a foot of an operator is to be hung. The touring frame may include a touring body provided in a quadrilateral shape, and a gripping member configured to form a gripping hole on each of an upper side and a lower side of the touring body.

The display device may further include a standard frame portion coupled to the base frame portion and including a tilting portion that adjusts a coupling angle on its both sides. The standard frame portion may include a support frame configured to form a framework in a quadrilateral shape, a first tilting portion disposed on one of a left side and a right side of the support frame, including an insertion hole, and configured to adjust an angle of a portion to be coupled, and a second tilting portion disposed at a position opposite to a position of the first tilting portion, configured to protrude outward from the support frame, and coupled to a neighboring first tilting portion, and configured to adjust an angle of a portion to be coupled.

### BRIEF DESCRIPTION OF DRAWINGS

FIG. 1 is a perspective view illustrating a structure in which two display devices are horizontally connected according to example embodiments.

FIG. 2 is a front view illustrating a structure in which a plurality of display devices is connected according to example embodiments.

FIG. 3 is a perspective view illustrating a state in which two display devices are separate to be side by side according to example embodiments.

FIG. 4 is a perspective view illustrating a state in which an image panel and a control module are provided to a base frame portion according to example embodiments.

FIG. 5 is a perspective view illustrating a state in which an image panel is detached from a base frame portion according to example embodiments.

FIG. 6 is a perspective view illustrating a state in which an image panel moves through a first service space portion according to example embodiments.

FIG. 7 is a perspective view illustrating a state in which a control module is provided to a base frame portion according to example embodiments.

FIG. 8 is a perspective view illustrating a state in which a second mount connecting portion rotates and forms a second service space portion according to example embodiments.

FIG. 9 is a perspective view illustrating a state in which a control module moves through a second service space portion according to example embodiments.

FIG. 10 is a perspective view illustrating a first connecting member and second connecting member according to example embodiments.

FIG. 11 is a cross-sectional view illustrating a first connecting member and a second connecting member according to example embodiments.

FIG. 12 is a perspective view illustrating a base frame portion according to example embodiments.

FIG. 13 is a perspective view illustrating a second connecting portion according to example embodiments.

FIG. 14 is an exploded perspective view of a second connecting portion according to example embodiments.

FIG. 15 is a perspective view illustrating a first connecting portion according to example embodiments.

FIG. 16 is an exploded perspective view of a first connecting portion according to example embodiments.

FIG. 17 is a cross-sectional view illustrating a state in which a first connecting portion and a second connecting portion face each other according to example embodiments.

FIG. 18 is a cross-sectional view illustrating a state in which a second coupling protrusion body is inserted into a connecting hole according to example embodiments.

FIG. 19 is a cross-sectional view illustrating a state in which a second stopping bead is stopped at an inner side of a second connecting body according to example embodiments.

FIG. 20 is a cross-sectional view illustrating a state in which a second coupling lever rotates and pulls a first connecting body to be separate away from a second connecting portion and thereby is fastened according to example embodiments.

FIG. 21 is a cross-sectional view illustrating a coupling protruding portion according to example embodiments.

FIG. 22 is a cross-sectional view illustrating a standard frame portion according to example embodiments.

FIG. 23 is an enlarged perspective view illustrating a second tilting portion according to example embodiments.

FIG. 24 is an enlarged perspective view illustrating a second tilting portion according to example embodiments.

FIG. 25 is an exploded perspective view illustrating a first tilting portion according to example embodiments.

FIG. 26 is an enlarged perspective view illustrating an inside of a first housing according to example embodiments.

FIG. 27 is a perspective view illustrating a touring frame according to example embodiments.

FIG. 28 is a perspective view illustrating a first touring combining portion according to example embodiments.

FIG. 29 is a perspective view illustrating a state in which an image panel and a touring frame are coupled to a base frame portion according to example embodiments.

FIG. 30 is a perspective view illustrating a state in which an image panel and a standard frame portion are coupled to a base frame portion according to example embodiments.

FIGS. 31 and 32 are perspective views illustrating a state in which an image panel, a standard frame portion, and a touring frame are coupled to a base frame portion according to example embodiments.

### DETAILED DESCRIPTION OF THE INVENTION

Hereinafter, a display device according to example embodiments will be described with reference to the accompanying drawings. Herein, thicknesses of lines, sizes of constituent elements, etc., illustrated in the drawings, may be exaggerated for clarity and convenience of description.

Further, terms described in the following are ones defined based on functions in the present disclosure and thus, may vary based on the intent of a user or an operator, or custom. Accordingly, the definition of such terms should be made based on the overall description disclosed in the present specification.

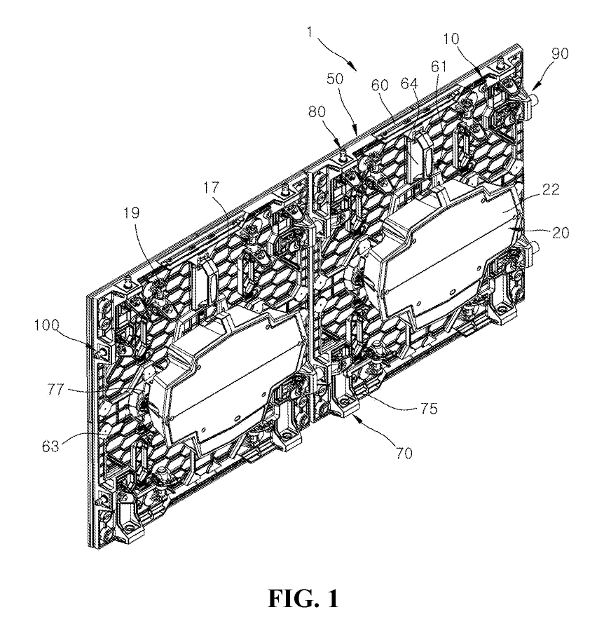

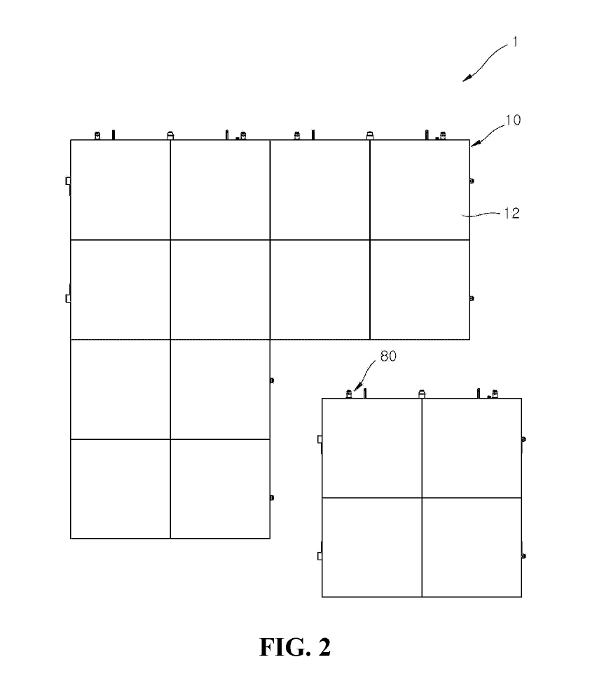

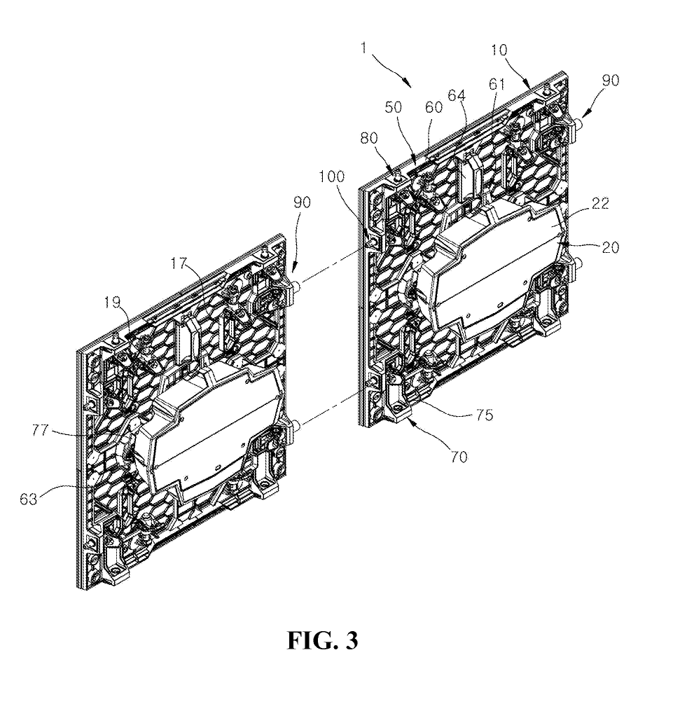

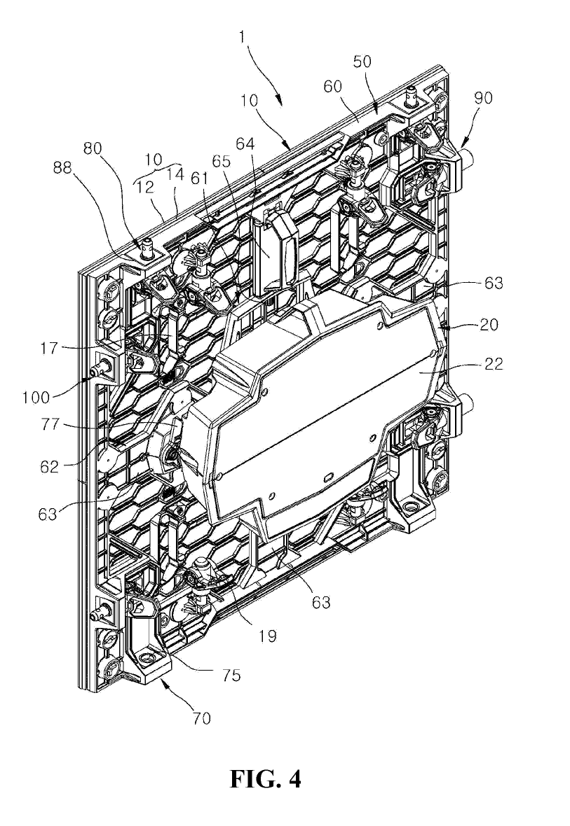

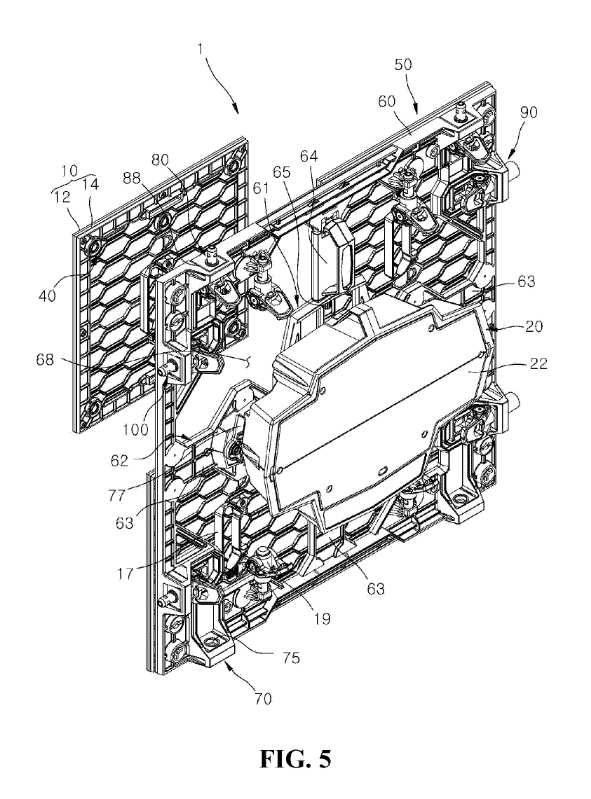

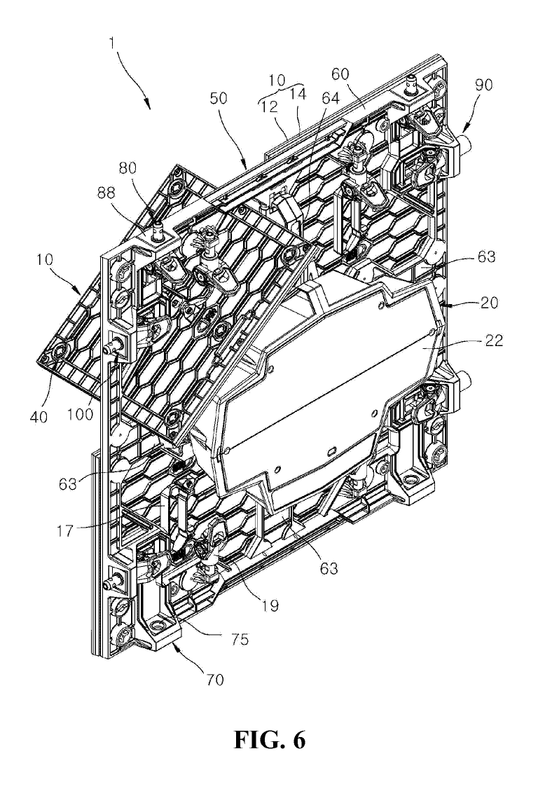

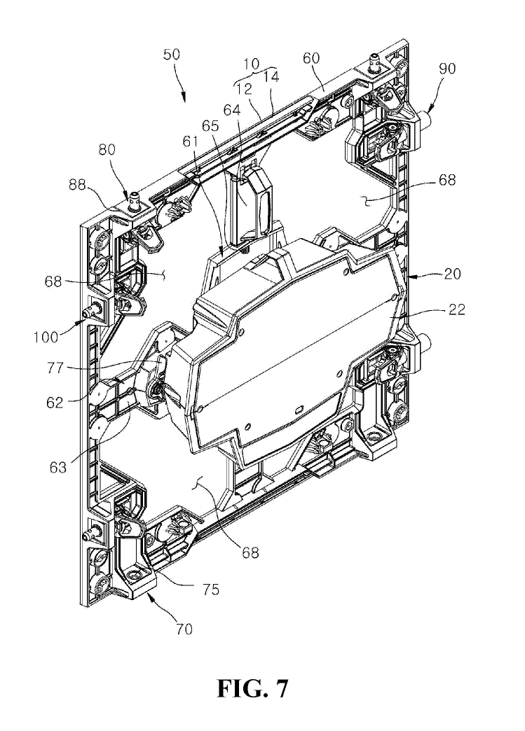

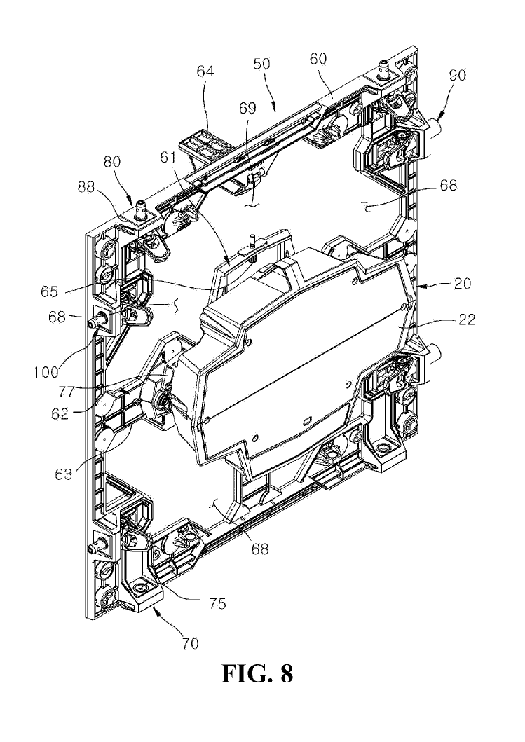

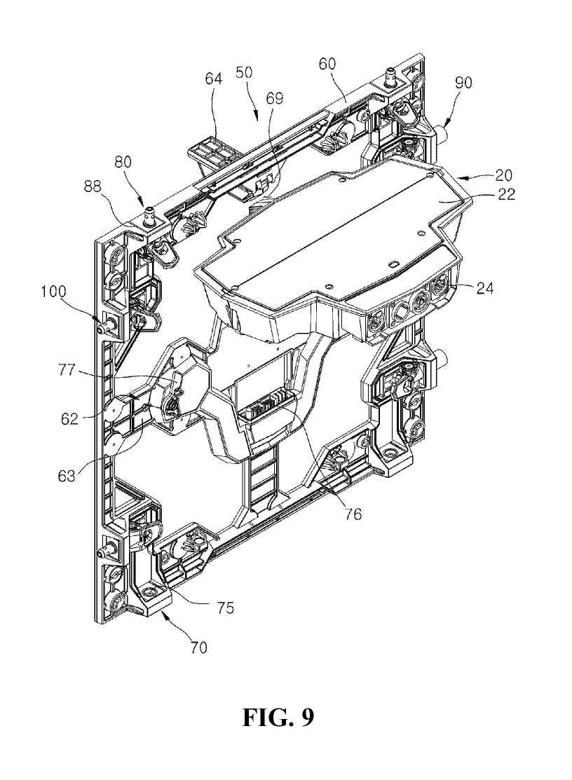

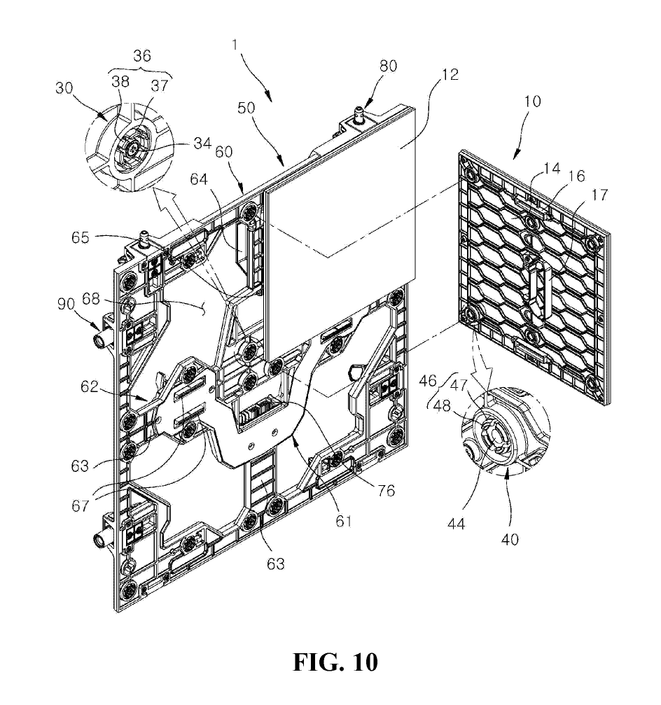

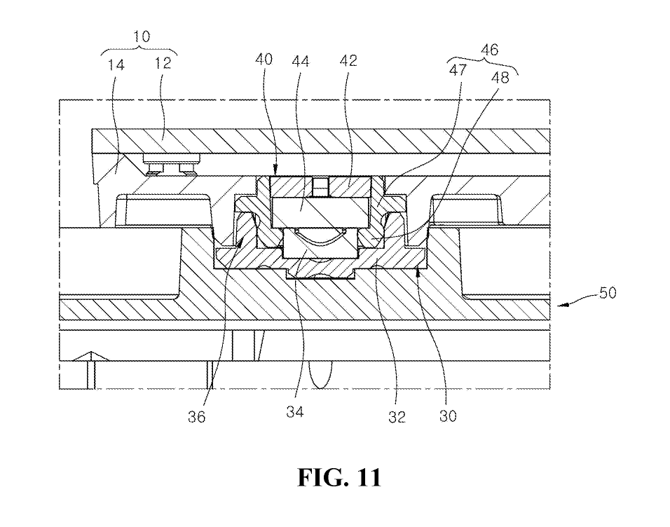

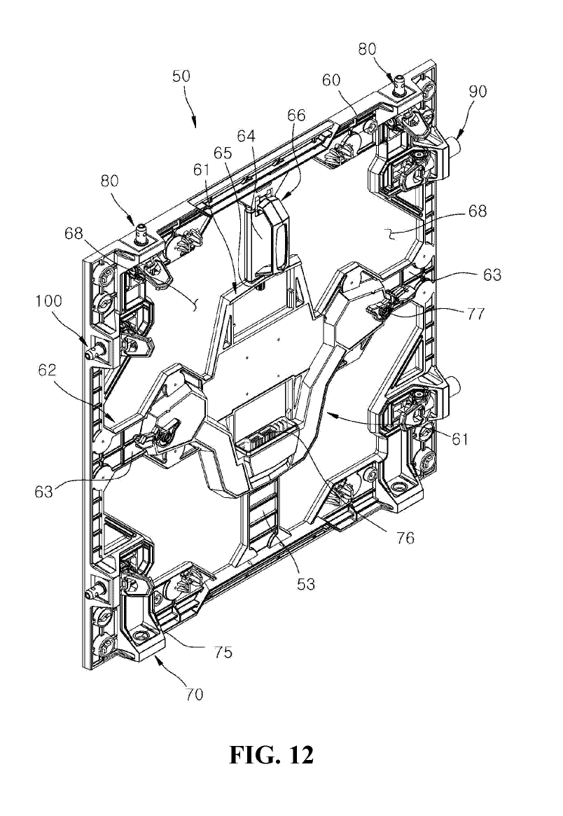

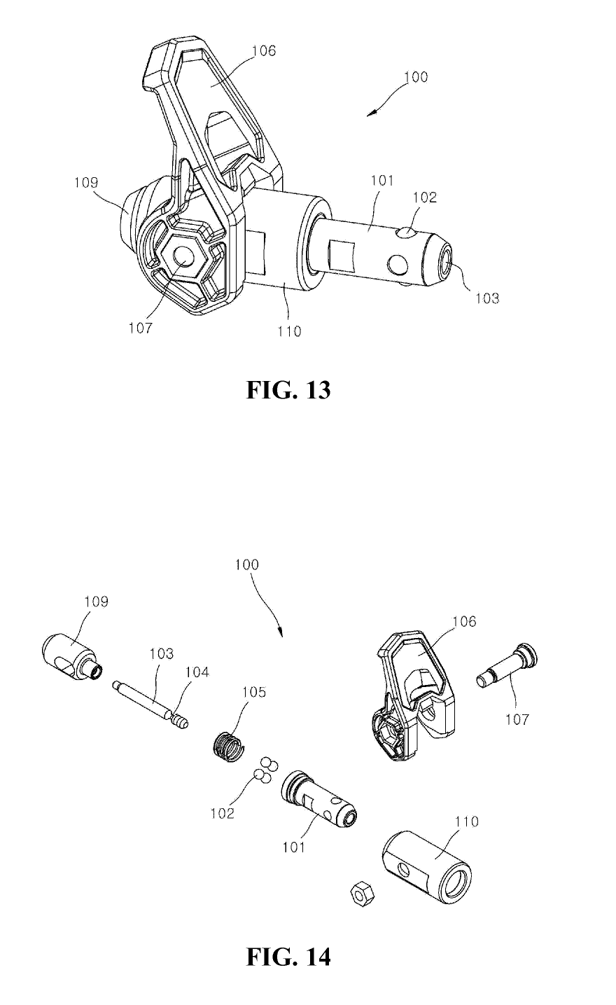

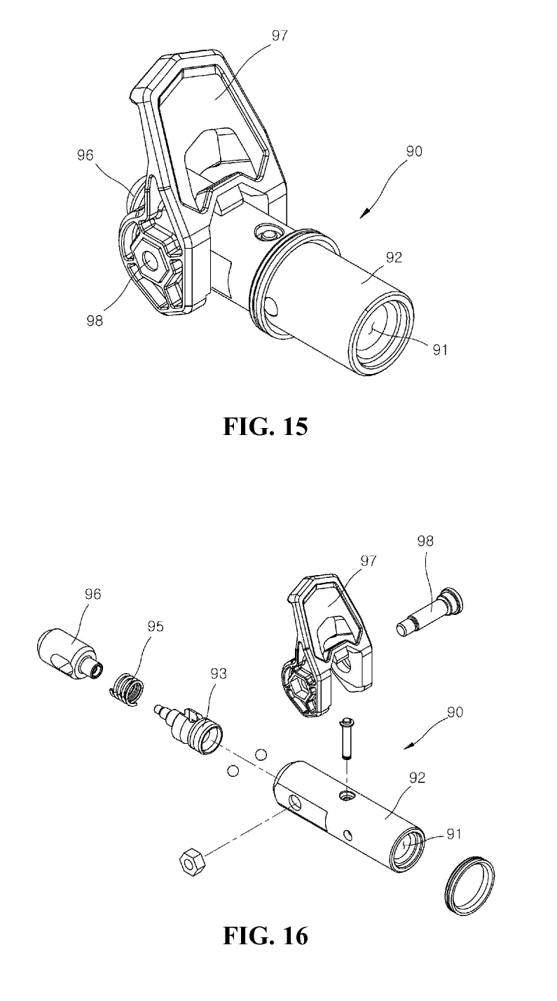

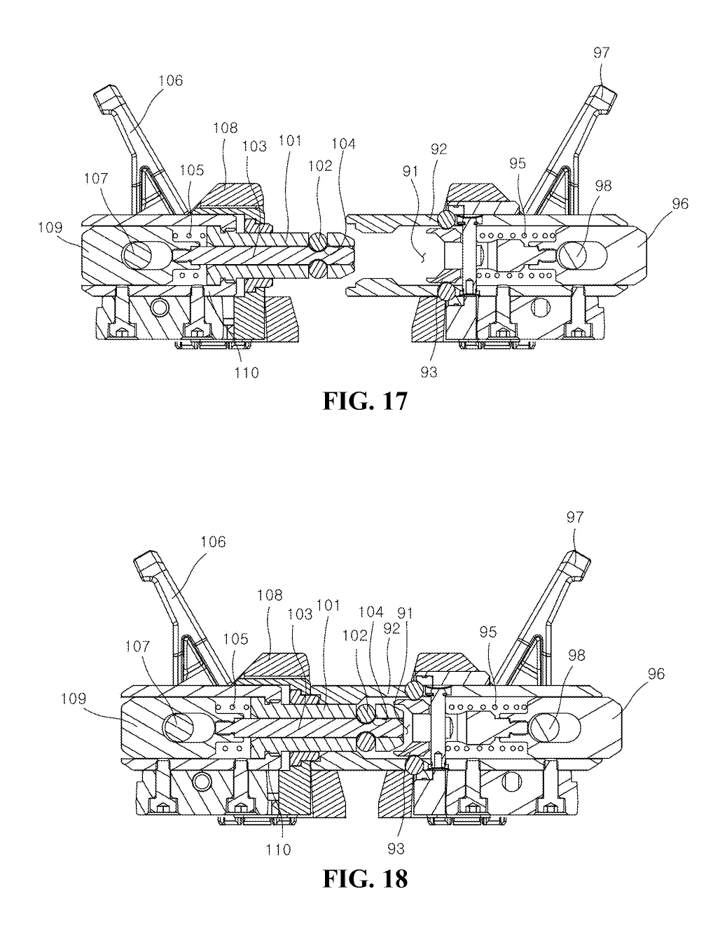

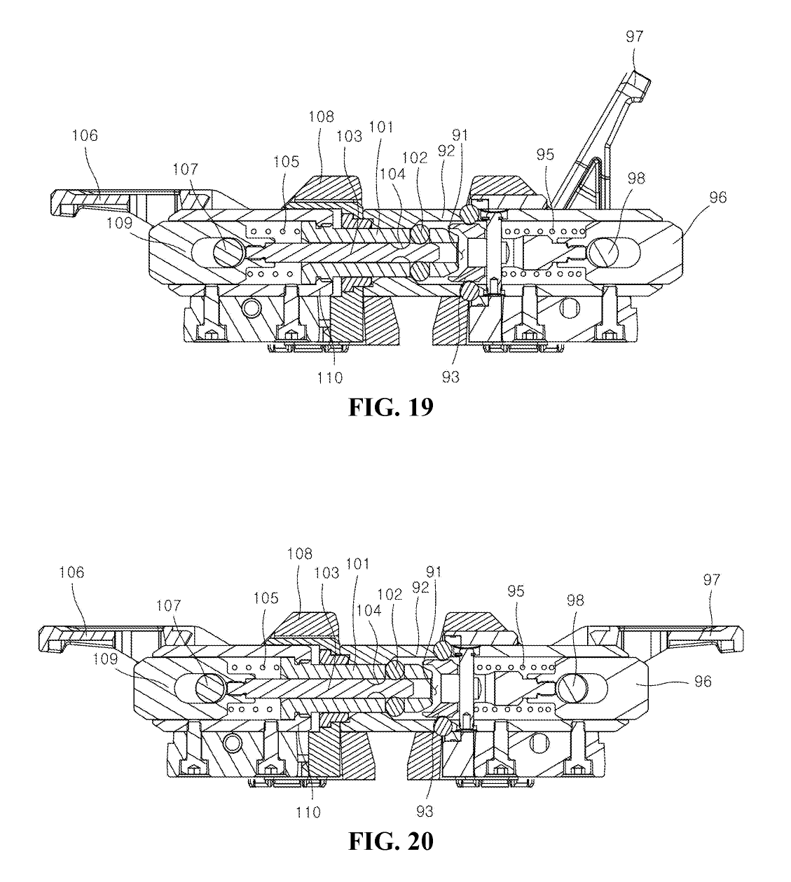

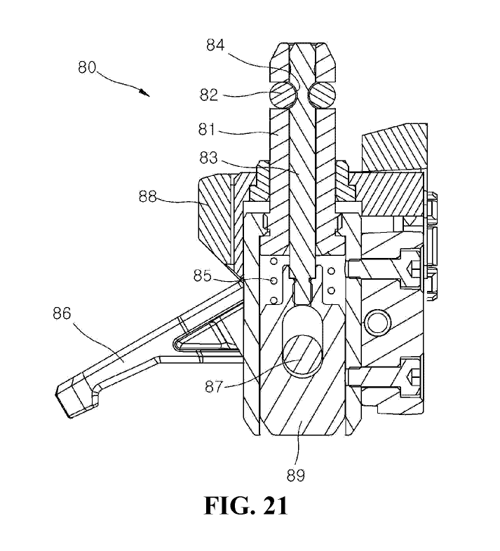

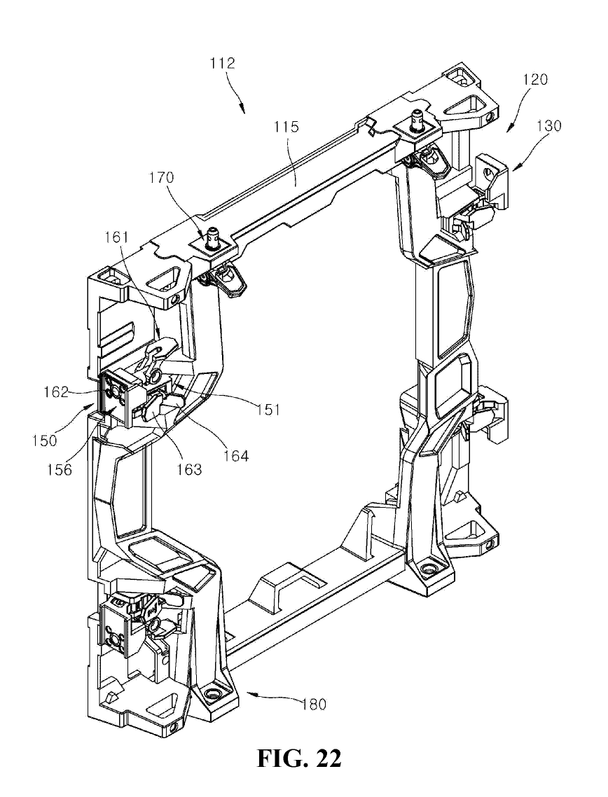

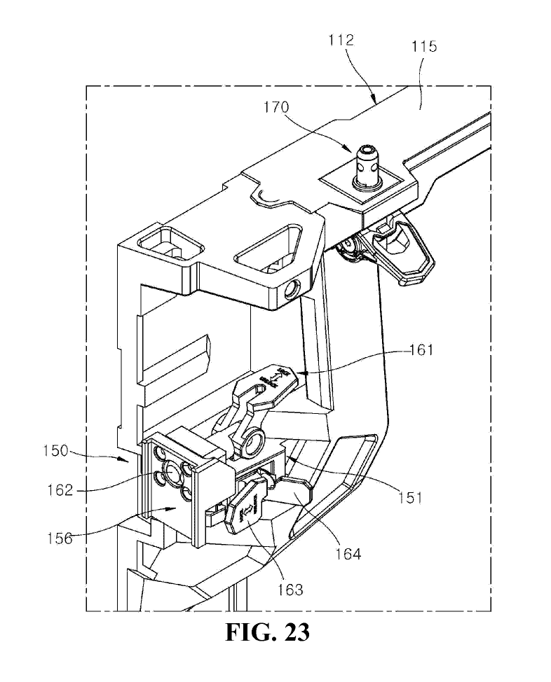

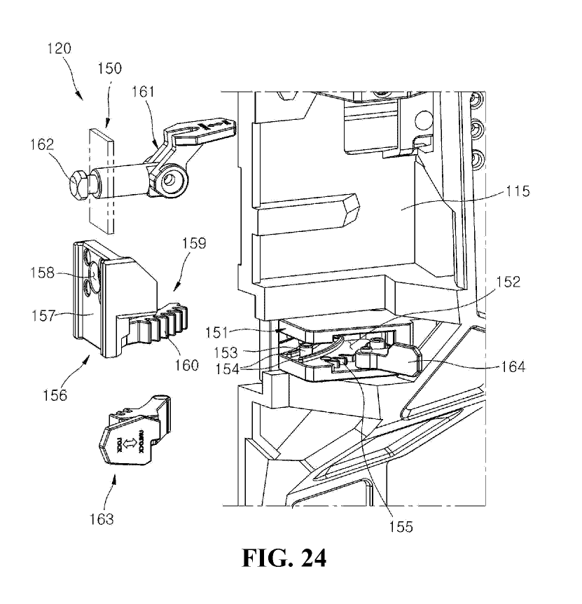

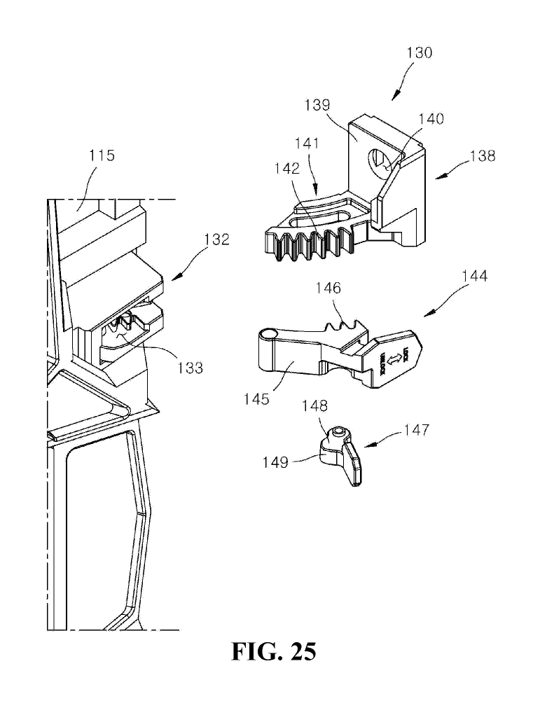

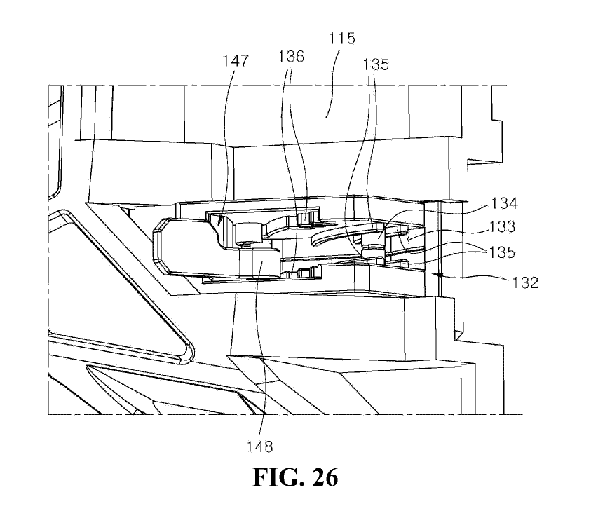

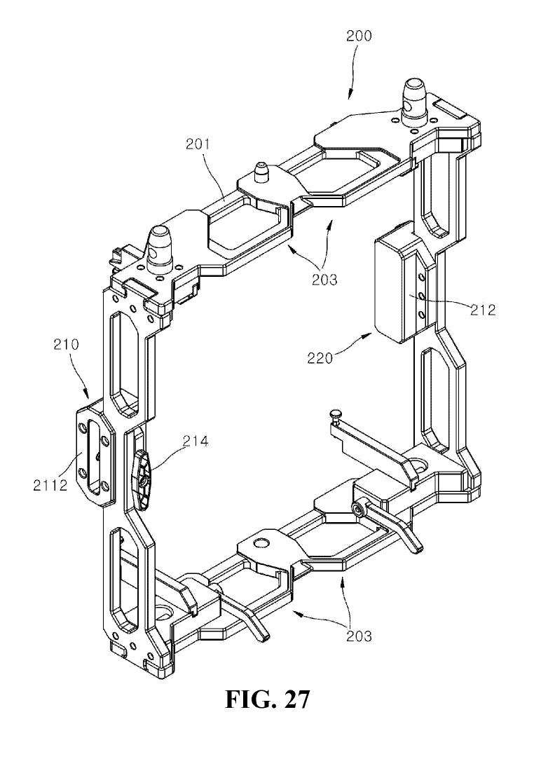

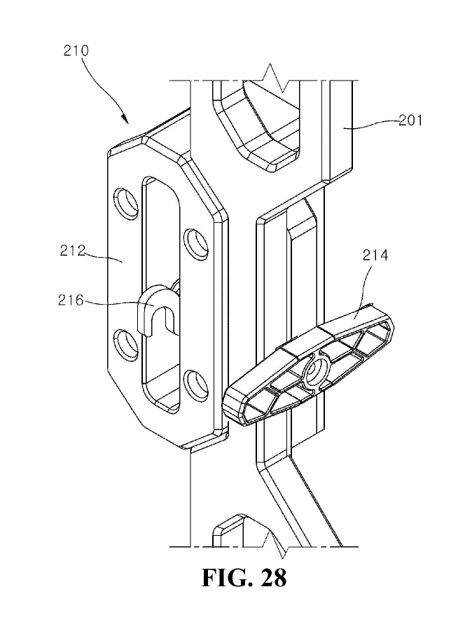

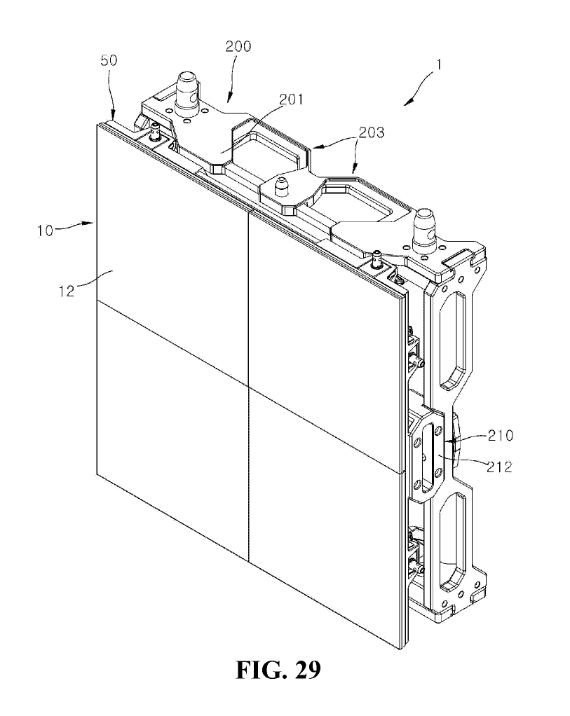

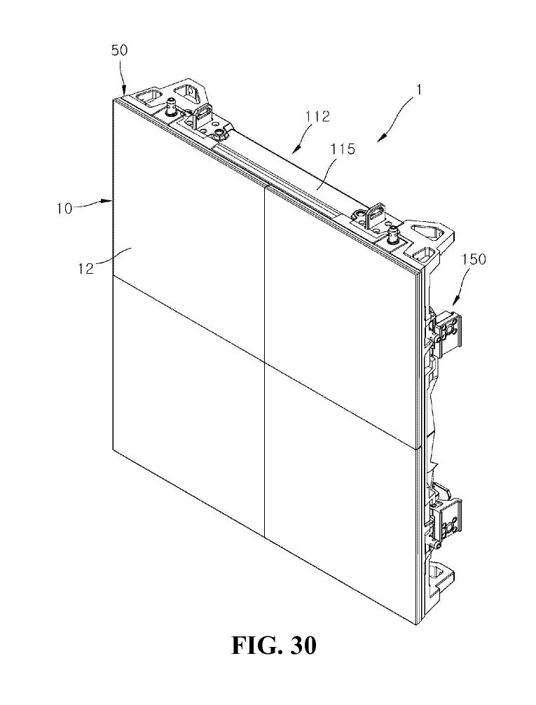

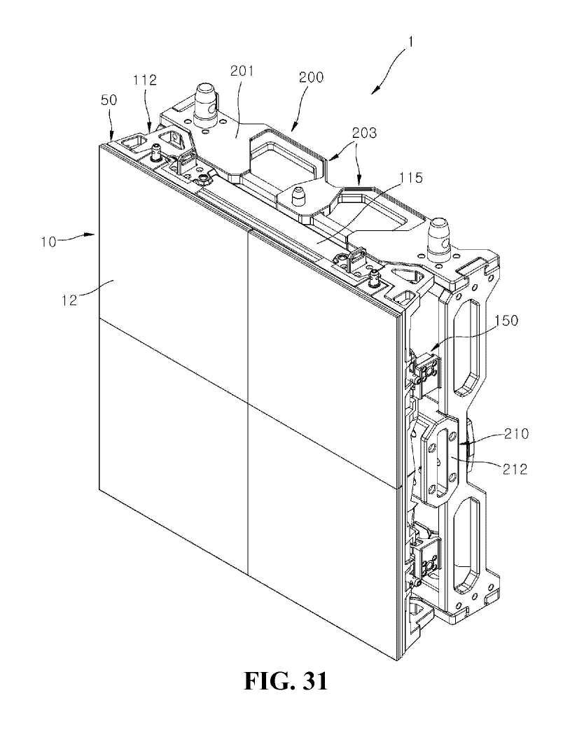

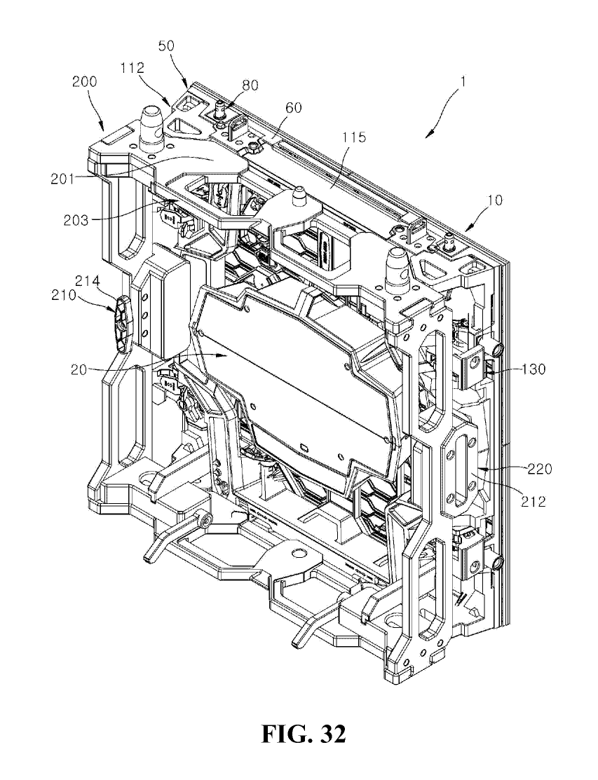

FIG. 1 is a perspective view illustrating a structure in which two display devices are horizontally connected according to example embodiments, FIG. 2 is a front view illustrating a structure in which a plurality of display devices is connected according to example embodiments, FIG. 3 is a perspective view illustrating a state in which two display devices are separate to be side by side according to example embodiments, FIG. 4 is a perspective view illustrating a state in which an image panel and a control module are provided to a base frame portion according to example embodiments, FIG. 5 is a perspective view illustrating a state in which an image panel is detached from a base frame portion according to example embodiments, FIG. 6 is a perspective view illustrating a state in which an image panel moves through a first service space portion according to example embodiments, FIG. 7 is a perspective view illustrating a state in which a control module is provided to a base frame portion according to example embodiments, FIG. 8 is a perspective view illustrating a state in which a second mount connecting portion rotates and forms a second service space portion according to example embodiments, FIG. 9 is a perspective view illustrating a state in which a control module moves through a second service space portion according to example embodiments, FIG. 10 is a perspective view illustrating a first connecting member and second connecting member according to example embodiments, FIG. 11 is a cross-sectional view illustrating a first connecting member and a second connecting member according to example embodiments, FIG. 12 is a perspective view illustrating a base frame portion according to example embodiments, FIG. 13 is a perspective view illustrating a second connecting portion according to example embodiments, FIG. 14 is an exploded perspective view of a second connecting portion according to example embodiments, FIG. 15 is a perspective view illustrating a first connecting portion according to example embodiments, FIG. 16 is an exploded perspective view of a first connecting portion according to example embodiments, FIG. 17 is a cross-sectional view illustrating a state in which a first connecting portion and a second connecting portion face each other according to example embodiments, FIG. 18 is a cross-sectional view illustrating a state in which a second coupling protrusion body is inserted into a connecting hole according to example embodiments, FIG. 19 is a cross-sectional view illustrating a state in which a second stopping bead is stopped at an inner side of a second connecting body according to example embodiments, FIG. 20 is a cross-sectional view illustrating a state in which a second coupling lever rotates and pulls a first connecting body to be separate away from a second connecting portion and thereby is fastened according to example embodiments, FIG. 21 is a cross-sectional view illustrating a coupling protruding portion according to example embodiments, FIG. 22 is a cross-sectional view illustrating a standard frame portion according to example embodiments, FIG. 23 is an enlarged perspective view illustrating a second tilting portion according to example embodiments, FIG. 24 is an enlarged perspective view illustrating a second tilting portion according to example embodiments, FIG. 25 is an exploded perspective view illustrating a first tilting portion according to example embodiments, FIG. 26 is an enlarged perspective view illustrating an inside of a first housing according to example embodiments, FIG. 27 is a perspective view illustrating a touring frame according to example embodiments, FIG. 28 is a perspective view illustrating a first touring combining portion according to example embodiments, FIG. 29 is a perspective view illustrating a state in which an image panel and a touring frame are coupled to a base frame portion according to example embodiments, FIG. 30 is a perspective view illustrating a state in which an image panel and a standard frame portion are coupled to a base frame portion according to example embodiments, and FIGS. 31 and 32 are perspective views illustrating a state in which an image panel, a standard frame portion, and a touring frame are coupled to a base frame portion according to example embodiments.

As illustrated in FIGS. 1, 5, 10, 22, 27, and FIGS. 29 through 32, a display device 1 according to example embodiments includes an image panel 10, a control module 20, a first connecting portion 90, a second connecting portion 100, a base frame portion 50, a standard frame portion 112, and a touring frame 200. Constituent elements may be coupled to each other or separate from each other selectively based on a necessity.

As illustrated in FIGS. 5 and 10, a variety of light emitting devices may be used for the image panel 10 without departing from the technical sprit that a plurality of light emitting elements 12 is arranged in a planar shape. The image panel 10 according to example embodiments includes the light emitting element 12, a panel body 14, a panel terminal 16, a gripping knob 17, and a panel fastening portion 19.

The image panel 10 is provided in a quadrilateral shape and is coupled to the base frame portion 50 through a magnetic force. A plurality of image panels 10 is dispose on one side (a right side in FIG. 10) of the base frame portion 50 to continue therefrom.

The light emitting element 12 may use a light emitting diode (LED). In addition thereto, other light emitting members that configure color may be employed for the light emitting element 12.

The panel body 14 is provided in a rectangular planar shape. A plurality of light emitting elements 12 is disposed on a front portion of the panel body 14. The panel terminal 16 is provided on the side of the panel body 14 that faces the base frame portion 50. The panel terminal 16 is coupled to an output terminal 67 provided to the base frame portion 50 to be supplied with an image signal and a power. The gripping knob 17 is rotatably disposed on the side of the panel body 14 on which the light emitting element 12 is absent. Accordingly, when carrying or installing the image panel 10, it is possible to easily move the image panel 10 with holding the gripping knob 17, thereby enhancing the work efficiency.

Also, the panel fastening portion 19 is disposed inside the image panel 10 (a right side in FIG. 5). The panel fastening portion 19 includes a protrusion and the protrusion is inserted into a hole formed on the base frame portion 50 and thereby fastened thereto. Accordingly, it is possible to prevent the image panel 10 from being separate from the base frame portion 50. A configuration and an operation state of the panel fastening portion 19 is the same as a configuration and an operation state of the second connecting portion 100, which will be described later. Accordingly, a description related thereto will be omitted.

As illustrated in FIGS. 4 and 9, various types of control devices may be used for the control module 20 without departing from the technical sprit that the control module 20 is connected to the image panel 10 by way of the base frame portion 50 to supply a control signal and a power. The control module 20 according to example embodiments includes a control body 22 configured to fasten to the other side of the base frame portion 50, a connecting terminal 24 configured to protrude outward from the control body 22, and an input terminal (not shown) connected to a fixed terminal 76 that is provided to the base frame portion 50 and configured to supply the control signal and the power to the image panel 10. The connecting terminal 24 is connected to an external cable that supplies power and an image signal. The input terminal is provided on the side of the control body 22 that faces the fixed terminal 76 and thereby is connected to the fixed terminal 76. Accordingly, the image signal transferred through an external cable is transferred to the control body 22 through the connecting terminal 24. The image signal and the power from the control body 22 are transferred to the panel terminal 16 of the image panel 10 through the fixed terminal 76 of the base frame portion 50.

As illustrated in FIGS. 10 and 11, the first connecting member 30 may be transformed to a variety of shapes without departing from the technical sprit that the first connecting member 30 is fastened to the base frame portion 50 and has a magnetic force. The first connecting member 30 according to example embodiments includes a first connecting housing 32, a first bonding member 34, and a first stopper 36.

The first connecting housing 32 is fastened to the base frame portion 50. A plurality of first connecting members 30 is disposed on a front portion of the base frame portion 50 that faces the image panel 10. The first connecting housing 32 is inserted into a groove formed on the base frame portion 50 and thereby mounted thereto. The first connecting housing 32 according to example embodiments is provided in a circular plate shape.

The first bonding member 34 is fastened to the first connecting housing 32 and has a magnetic force. The first bonding member 34 uses a permanent magnet and is fastened at the center of the first connecting housing 32.

The first stopper 36 may be provided in a variety of shapes without departing from the technical spirit that the first stopper 36 protrudes along the periphery of the first bonding member 34 and is fastened by being stopped by a second connecting member 40. The first stopper 36 according to example embodiments includes a first boundary member 37 configured to protrude outward from the first connecting housing 32 to be in a ring shape and a first hook member 38 configured to be separate from the first boundary member 37 and to protrude outward from the first connecting housing 32 to be in a hook shape.

The first boundary member 37 and the first hook member 38 are provided in a protruding shape from the first connecting housing 32 along the outer circumference of the first bonding member 34. The first boundary member 37 and the first hook member 38 are integrally formed with the first connecting housing 32, and the first boundary member 37 and the first hook member 38 protrude from the first connecting housing 32 to be in a ring shape.

The first boundary member 37 and the first hook member 38 are alternately disposed in a circular arc direction along an outer side of the first bonding member 34. A hook shape for being stopped by the first connecting member 30 is provided inside the first boundary member 37 and the first hook member 38.

The second connecting member 40 may be transformed to a variety of shapes without departing from the technical sprit that the second connecting member 40 is fastened to the image panel 10 that faces the first connecting member 30, and is fastened to the first connecting member 30 through a magnetic force. The second connecting member 40 according to example embodiments includes a second connecting housing 42, a second bonding member 44, and a second stopper 46.

A plurality of second connecting members 40 is provided on one side of the image panel 10 that faces the base frame portion 50. The second connecting housing 42 is inserted into a groove formed on one side of the image panel 10 and thereby mounted thereto. The second connecting housing 42 according to example embodiments is provided in a circular plate shape.

The second bonding member 44 is fastened to the second connecting housing 42 and is molded using iron or a magnet as a material. The second bonding member 44 may use a permanent magnet or an iron bonded to the first bonding member 34, and is fastened at the center of the second connecting housing 42 that faces the first bonding member 34.

The second stopper 46 protrudes along the periphery of the second bonding member 44 and is fastened by being stopped by the first stopper 36. The second stopper 46 according to example embodiments includes a second boundary member 47 configured to protrude outward from the second connecting housing 42 to be in a ring shape and to make the first hook member 38 be stopped at its side, and a second hook member 48 configured to protrude inward from the second boundary member 47 and to grip the second bonding member 44.

The second boundary member 47 is provided in a protruding shape from the second connecting housing 42 along the outer circumference of the second bonding member 44. The second boundary member 47 is integrally formed with the second connecting housing 42. A groove portion at which the first hook member 38 of the first stopper 36 is stopped is formed in a circumferential direction at an outer side of the second boundary member 47. The second hook member 48 is connected at one end of the second boundary member 47. The second hook member 48 is provided in a shape to be stopped at one end of the second bonding member 44 in order to grip the second bonding member 44.

Accordingly, when the image panel 10 is fastened to the base frame portion 50, the first bonding member 34 of the first connecting member 30 and the second bonding member 44 of the second connecting member 40 are primarily fastened through a magnetic force and secondarily fastened through a structure in which the first stopper 36 is stopped at the outer side of the second stopper 46. Accordingly, installation and de-installation of the image panel 10 may be easily performed, thereby saving personnel expenses and reducing an operation time.

As illustrated in FIGS. 5, 10, and 12, the base frame portion 50 may be transformed to a variety of shapes without departing from the technical spirit that the image panel 10 is detachably disposed on one side of the base frame portion 50 and the control module 20 is detachably provided on the other side thereof. The base frame portion 50 that is a frame to which the image panel 10 is to be fastened is provided at a position that faces the image panel 10. The base frame portion 50 according to example embodiments includes a base body 60, a detachable mounting portion 61, an inner connecting portion 62, a first service space portion 68, a second service space portion 69, a coupling portion 70, a coupling protruding portion 80, the first connecting portion 90, and the second connecting portion 100.

The base body 60 forms a frame in a quadrilateral shape. The base body 60 according to example embodiments forms a quadrilateral frame and forms a framework of the base frame portion 50.

The detachable mounting portion 61 is provided inside the base body 60 to be separate from the base body 60, and enables detachment of the control module 20. The detachable mounting portion 61 is provided in a plate shape, and a body locking lever 77 is rotatably provided to the detachable mounting portion 61. Also, the fixed terminal 76 for connecting to the control module 20 is provided to the detachable mounting portion 61. When the control module 20 becomes in contact with the detachable mounting portion 61 in a state in which the control module 20 is connected to the fixed terminal 76, the body locking lever 77 rotates and is stopped at the side of the control module 20. Accordingly, the control module 20 is fastened to the detachable mounting portion 61.

The inner connecting portion 62 may be transformed to a variety of shapes without departing from the technical spirit that the inner connecting portion 62 connects the detachable mounting portion 61 to the base body 60 and fastens the detachable mounting portion 61 inside the base body 60. The inner connecting portion 62 according to example embodiments extends upward and downward (in FIG. 12) and leftward and rightward from the detachable mounting portion 61 and is connected to the base body 60. The first service space portion 68 is formed in a diagonal direction of the base frame portion 50. Since four inner connecting portion 62 are disposed based on the detachable mounting portion 61, four first service space portions 68 are formed inside the base body 60.

The first service space portion 68 refers to a space through which the image panel 10 moves. The image panel 10 disposed on the front portion of the base frame portion 50 may be retracted to a rear portion of the base frame portion 50 through the first service space portion 68. To form the first service space portion 68, a groove may be formed in a diagonal direction in a space formed by the base body 60, the detachable mounting portion 61, and the inner connecting portion 62, thereby enabling the image panel 10 to move.

The inner connecting portion 62 according to example embodiments includes a first mount connecting portion 63 of which both sides are fastened to the base body 60 and the detachable mounting portion 61 and a second mount connecting portion 64 of which one side is rotatably connected to the base body 60 and of which another side is coupled to the detachable mounting portion 61.

The first mount connecting portions 63 are connected to left and right sides and the lower side of the detachable mounting portion 61, and the second mount connecting portion 64 is connected to the upper side of the detachable mounting portion 61. A hinge connecting portion 66 is provided to the upper side of the second mount connecting portion 64 and is hinge-connected to the base body 60, and the lower side of the second mount connecting portion 64 is fastened to the detachable mounting portion 61. Since a coupling bolt 65 that passes through the detachable mounting portion 61 is coupled at the lower side of the second mount connecting portion 64, the second mount connecting portion 64 is fastened to the detachable mounting portion 61. Depending on a necessity, when retracting the control module 20 to the front portion of the base frame portion 50, the second service space portion 69 is formed by an operation of releasing coupling of the coupling bolt 65 and rotating the second mount connecting portion 64.

That is, while the second mount connecting portion 64 is separate from the detachable mounting portion 61 and rotates based on the base body 60, the second service space portion 69 through which the control module 20 moves is formed. The second service space portion 69 is formed by an operation of rotating the second mount connecting portion 64 and by separating the second mount connecting portion 64 from the detachable mounting portion 61.

The second service space portion 69 refers to an inner space of the base body 60 formed by the base body 60 to which the detachable mounting portion 61 and the first mount connecting portion 63 and the second mount connecting portion 64 connected to the left and right sides of the detachable mounting portion 61 are connected. In the meantime, since a separate knob is provided to the second mount connecting portion 64, an operation of gripping and rotating the second mount connecting portion 64 may be easily performed.

The output terminal 67 connected to the image panel 10 is provided to the front portion of the base frame portion 50 (in FIG. 10). The output terminal 67 is disposed on a front portion of the inner connecting portion 62, and is electrically connected to the fixed terminal 76 that is provided to the detachable mounting portion 61. The panel terminal 16 is provided to the image panel 10 that faces the output terminal 67, and is connected to the output terminal 67 in an insertion manner.

The number of output terminals 67 and the number of panel terminals 16 are molded in correspondence to the number of image panels 10. Since the panel terminal 16 and the output terminal 67 are coupled to each other, an image signal and a power output from the control module 20 are easily transferred to the image panel 10 through the base frame portion 50. Accordingly, since a separate wiring operation is not required, it is possible to save personnel expenses and installation cost and to reduce an operation time.

The image panel 10 may move to the first service space portion 68 formed between the inner connecting portion 62 and the base body 60. The control module 20 may move to the second service space portion 69 formed by a rotation of the second mount connecting portion 64.

The coupling portion 70 is provided on one of an upper side and a lower side of the base body 60 and includes a fastening hole 75. The coupling portion 70 according to example embodiments is provided on each of a left side and a right side of the lower side of the base body 60. The coupling portion 70 protruded laterally from the base body 60 and internally includes the fastening hole 75.

As illustrated in FIGS. 12 and 21, the coupling protruding portion 80 is disposed at a position opposite to a position of the coupling portion 70 in the base body 60, and protrudes outward from the base body 60, and is inserted into the coupling portion 70 of the neighboring base frame portion 50 and thereby fastened thereto. The coupling protruding portion 80 according to example embodiments may be transformed to a variety of shapes without departing from the above technical sprit. The coupling portion 70 according to example embodiments includes a coupling protrusion body 81, a stopping bead 82, an inner moving member 83, an inner returning member 85, a coupling lever 86, a support connecting shaft 87, a mounting frame 88, and a control member 89.

An operation space is provided inside the coupling protrusion body 81, and one side (an upper side in FIG. 21) of the coupling protrusion body 81 is inserted into the fastening hole 75. The coupling protrusion body 81 is fastened to the mounting frame 88 connected to the upper side of the base body 60, and disposed in a vertical direction.

The stopping bead 82 is provided on one side of the coupling protrusion body 81 and is disposed to be movable inward and outward relative to the coupling protrusion body 81.

The inner moving member 83 moves in a lengthwise direction along the inner side of the coupling protrusion body 81, and includes an inner groove portion 84 that receives the stopping bead 82. When the stopping bead 82 is stopped by the inner groove portion 84, the stopping bead 82 moves inward relative to the coupling protrusion body 81. When the stopping bead 82 is not stopped by the inner groove portion 84, the stopping bead 82 protrudes outward relative to the coupling protrusion body 81. The control member 89 to which a control power of a user is to be transferred is provided to the inner moving member 83. The control member 89 has a diameter greater than a diameter of the inner moving member 83 and is positioned at an outer side of the coupling protrusion body 81.

The inner returning member 85 is disposed between the inner moving member 83 and the coupling protrusion body 81, and elastically pressurizes the control member 89 of the inner moving member 83 to be separate away from the stopping bead 82. For example, the inner returning member 85 may use a coil spring.

The coupling lever 86 is rotatably disposed at the outer side of the coupling protrusion body 81, and includes a protrusion in a cam shape on its side. The coupling lever 86 makes the coupling protrusion body 81 move backward (a lower side in FIG. 21) in contact with the mounting frame 88 that supports the coupling protrusion body 81 through a rotating motion. The coupling protrusion body 81 includes a portion formed in a cylindrical shape at an outer side of the inner moving member 83 and a portion formed in a cylindrical shape at an outer side of the inner returning member 85. Two members are combined with each other in an insertion manner.

The support connecting shaft 87 is disposed to pass through the coupling lever 86, the coupling protrusion body 81, and the inner moving member 83.

Describing an operation of combining the coupling protruding portion 80 with the coupling portion 70, when upwardly pressurizing the control member 89 after inserting the coupling protrusion body 81 into the fastening hole 75 of the coupling portion 70, the inner moving member 83 released from the stopping of the stopping bead 82 moves downwardly by an elastic force of the inner returning member 85. Through the movement of the inner returning member 85, the stopping bead 82 protrudes outward from the coupling protrusion body 81 and is stopped at the inner side of the coupling portion 70 whereby the coupling protruding portion 80 is combined with the coupling portion 70.

When rotating the coupling lever 86, the coupling lever 86 rotates and moves downwardly by being pushed by the mounting frame 88 since a body of the coupling lever 86 connected to the support connecting shaft 87 is formed in a cam shape. The support connecting shaft 87 moves downwardly together with the coupling lever 86, and the coupling protrusion body 81 and the stopping bead 82 move downwardly together with the support connecting shaft 87. Thus, a force of the stopping bead 82 that combines with the coupling portion 70 increases and a clamping force between the coupling protruding portion 80 and the coupling portion 70 is also enhanced accordingly.

As illustrated in FIG. 12 and FIGS. 15 through 17, the first connecting portion 90 may be transformed to a variety of shapes without departing from the technical spirit that the first connecting portion 90 is disposed on one of left and right sides of the base body 60 and includes a connecting hole 91. The first connecting portion 90 according to example embodiments includes a first connecting body 92, a first inner moving member 93, a first inner returning member 95, a first connecting moving member 96, a first coupling lever 97, and a first support connecting shaft 98.

The first connecting body 92 includes an operation space that communicates with the connecting hole 91 and is provided in a shape of a pipe of which both sides are open. The first inner moving member 93 moves in a lengthwise direction along an inner side of the first connecting body 92, and includes a side hole portion 94 through which a bead shape is received. The first inner moving member 93 is disposed based on a first inner member and includes the first connecting moving member 96 controllable by the user in a pushing manner.

The first inner returning member 95 elastically pressurizes the first connecting moving member 96 of the first inner moving member 93 to be separate away from the connecting hole 91.

The first support connecting shaft 98 is disposed to pass through the first coupling lever 97, the first connecting body 92, and the first connecting moving member 96. When rotating the first coupling lever 97 in a state in which the second connecting portion 100 is coupled to the first connecting portion 90, the first coupling lever 97 rotates and is pushed by the base body 60 that supports the first connecting portion 90 and moves to be separate away from the second connecting portion 100 since a body of the first coupling lever 97 connected to the first support connecting shaft 98 is formed in a cam shape. The first support connecting shaft 98 moves together with the first coupling lever 97 and the first connecting body 92 moves together with the first support connecting shaft 98. Thus, a clamping force of the second stopping bead 102 that connects the first connecting portion 90 and the second connecting portion 100 is enhanced accordingly.

As illustrated in FIGS. 12, 13, 14, and 17, the second connecting portion 100 is disposed at a position opposite to a position of the first connecting portion 90, protrudes outward from the base body 60, and is inserted into the first connecting portion 90 of the neighboring base frame portion 50 and thereby fastened thereto. The second connecting portion 100 may be transformed to a variety of shapes without departing from the above technical spirit. The second connecting portion 100 according to example embodiments includes a second coupling protrusion body 101, a second stopping bead 102, a second inner moving member 103, a second inner returning member 105, a second coupling lever 106, a second support connecting shaft 107, a second mounting frame 108, a second connection moving member 109, and a second connecting housing 110.

An operation space is provided inside the second coupling protrusion body 101, and one side (a right side in FIG. 17) of the second coupling protrusion body 101 is inserted into the first connecting body 92. The second coupling protrusion body 101 is fastened to the second mounting frame 108 connected to the left side (in FIG. 12) of the base body 60, and disposed in a horizontal direction.

The second stopping bead 102 is provided on one side of the second coupling protrusion body 101 and is disposed to be movable inward and outward relative to the second coupling protrusion body 101. The second stopping bead 102 is inserted into the connecting hole 91 of the first connecting portion 90 and stopped at a step portion provided inside the first connecting body 92.

The second inner moving member 103 moves in a lengthwise direction along the inner side of the second coupling protrusion body 101, and includes a second inner groove portion 104 that receives the second stopping bead 102. The second inner moving member 103 is provided in a circular bar shape.

When the second stopping bead 102 is stopped by the second inner groove portion 104, the second stopping bead 102 moves inward relative to the second coupling protrusion body 101. When the second stopping bead 102 is not stopped by the second inner groove portion 104, the second stopping bead 102 protrudes outward relative to the second coupling protrusion body 101. The second connection moving member 109 to which a control power of the user is to be transferred is provided to one side of the second inner moving member 103. The second connection moving member 109 has a diameter greater than a diameter of the second inner moving member 103 and is positioned at the outer side of the second coupling protrusion body 101.

The second inner returning member 105 is disposed between the second inner moving member 103 and the second coupling protrusion body 101, and elastically pressurizes the second connection moving member 109 of the second inner moving member 103 to be separate away from the second stopping bead 102. For example, the second inner returning member 105 may use a coil spring.

The second coupling protrusion body 101 includes the second connecting housing 110. The second connecting housing 110 is formed to have a diameter greater than a body of a second coupling protrusion and is provided in a shape of a pipe. The second connecting housing 110 is disposed to surround the outer side of the second coupling lever 106, the second support connecting shaft 107, and the second connection moving member 109.

The second coupling lever 106 is rotatably disposed at the outer side of the second coupling protrusion body 101, and includes a protrusion in a cam shape on its side. The second coupling lever 106 makes the second coupling protrusion body 101 move backward (a left side in FIG. 17) in contact with the second mounting frame 108 that supports the second coupling protrusion body 101 through a rotating motion.

The second coupling protrusion body 101 includes a portion formed in a cylindrical shape at an outer side of the second inner moving member 103 and a portion formed in a cylindrical shape at an outer side of the second inner returning member 105. Two members are combined with each other in an insertion manner.

The second support connecting shaft 107 is disposed to pass through the second coupling lever 106, the second coupling protrusion body 101, and the second inner moving member 103.

As illustrated in FIG. 22, the standard frame portion 112 may be transformed to a variety of shapes without departing from the technical spirit that the standard frame portion 112 is couple to the base frame portion 50 and includes a tilting portion 120 that adjusts a coupling angle on left and right sides of the standard frame portion 112. The standard frame portion 112 according to example embodiments includes a support frame 115, a tilting portion 120, a first tilting portion 130, a second tilting portion 150, a vertical locking portion 170, and a standard connecting portion 180.

The support frame 115 forms a framework in a quadrilateral shape, and the tilting portion 120 is provided to the support frame 115 and thereby is coupled to the neighboring standard frame portion 112 and at the same time, may adjust a coupling angle. The tilting portion 120 according to example embodiments includes a first tilting portion 130 and a second tilting portion 150.

As illustrated in FIGS. 22, 25, and 26, the first tilting portion 130 is disposed on one of the left and right sides of the support frame 115, and includes an insertion hole 140, thereby capable of adjusting an angle of a portion to be coupled. The first tilting portion 130 according to example embodiments includes a first housing 132, a first moving portion 138, a first lock member 144, and a second lock member 147.

The first housing 132 forms a first space 133 inside the support frame 115. In the first space 133, a first extending panel 141 of the first moving portion 138 moves and a first lock gear 146 of the first lock member 144 also moves. The first housing 132 according to example embodiments includes a first support protrusion 134 configured to pass through the first moving portion 138, a first guide protrusion 135 disposed on each of both sides of the first support protrusion 134 and configured to guide a rotation of the first moving portion 138 by being stopped at an outer side of the first moving portion 138, and a first fastening gear 136 configured to form a step in relation to the first guide protrusion 135, disposed on each of upper and lower sides of the first moving portion 138, and configured to form a gear in a circumferential direction.

The first space 133 forms a groove in a horizontal direction of the support frame 115. The first support protrusion 134 is vertically provided inside the first space 133. Since the first support protrusion 134 is disposed to pass through an inner side of a curved long hole that is provided to the first extending panel 141 of the first moving portion 138, it is possible to prevent the first moving portion 138 from being separate from the first housing 132.

The first guide protrusion 135 is a rail that faces the first space 133 and protrudes from each of the upper and lower sides of the first housing 132 to be in an arc shape. The first guide protrusion 135 guides a rotation of the first moving portion 138 together with the first extending panel 141 by being stopped at a stepped recess portion that is provided to the first extending panel 141.

The first fastening gear 136 is a gear that is formed in an arc shape on each of the upper and lower sides of the first housing 132 together with the first guide protrusion 135.

The first moving portion 138 is disposed to be movable inward and outward relative to the first housing 132, and includes the first moving panel 139 on which the insertion hole 140 is formed. The first moving portion 138 according to example embodiments includes the first moving panel 139, the first extending panel 141, and a first moving gear 142.

The first moving panel 139 is provided in a shape of a plate shape that is disposed to vertically stand, and includes the insertion hole 140. The first extending panel 141 extends laterally from the first moving panel 139 and is inserted into the first housing 132. A groove portion in an arc shape is provided to the first extending panel 141, and a stopping groove portion into which the first guide protrusion 135 is inserted and thereby stopped is formed at the outer side of the groove portion in the arc shape.

The first moving gear 142 forms a gear in a circumferential direction along the side of the first extending panel 141, and the first fastening gear 136 is disposed on each of upper and lower sides of the first moving gear 142.

The first lock member 144 is rotatably provided to the first housing 132, and confines a movement of the first moving portion 138 through an operation of engaging into the side of the first moving portion 138 of which movement is completed. The first lock member 144 according to example embodiments includes a first lock body 145 configured to face the first moving gear 142, and rotatably disposed inside the first housing 132 and the first lock gear 146 configured to form a gear along the side of the first lock body 145 and to engage into the first moving gear 142 and the first fastening gear 136 through a rotation of the first lock body 145. The first lock gear 146 may confine the rotation of the first moving portion 138 by being simultaneously stopped by the first moving gear 142 and the first fastening gear 136.

The second lock member 147 is rotatably disposed on the side of the first lock member 144, and moves to confine a rotation of the first lock member 144 after a locking operation of the first lock member 144 is completed, and confines unlocking of the first lock member 144. The second lock member 147 according to example embodiments includes a second lock body 148 configured to face the first lock body 145, and rotatably disposed inside the first housing 132 and a lock protrusion member 149 configured to protrude from the side of the second lock body 148 in a cam shape, and to confine the rotation of the first lock body 145 in contact with the first lock body 145 through a rotation of the second lock body 148. In a state in which the first lock member 144 rotates and thereby confines the rotation of the first moving portion 138, the second lock member 147 rotates and pushes the side of the first lock member 144 in contact with the second lock member 147 in the cam shape whereby the rotation of the first lock member 144 is confined.

As illustrated in FIGS. 22 through 24, the second tilting portion 150 is disposed at a position opposite to a position of the first tilting portion 130, protrudes outward from the support frame 115, and is coupled to the neighboring first tilting portion 130, thereby being capable of adjusting an angle of a portion to be coupled. The second tilting portion 150 according to example embodiments includes a second housing 151, a second moving portion 156, a connection coupling portion 161, a third lock member 163, and a fourth lock member 164.

The second housing 151 forms a second space 152 inside the support frame 115. In the second space 152, a second extending panel 159 of the second moving portion 156 moves and a second lock gear of the second lock member 147 also moves. The second housing 151 according to example embodiments includes a second support protrusion 153 configured to pass through the second moving portion 156, a second guide protrusion 154 disposed on each of both sides of the second support protrusion 153 and configured to guide a rotation of the second moving portion 156 by being stopped at an outer side of the second moving portion 156, and a second fastening gear 155 configured to form a step in relation to the second guide protrusion 154, disposed on each of upper and lower sides of the second moving portion 156, and configured to form a gear in a circumferential direction.

The second space 152 forms a groove in a horizontal direction of the support frame 115. The second support protrusion 153 is vertically provided inside the second space 152. Since the second support protrusion 153 is disposed to pass through an inner side of a curved long hole that is provided to the second extending panel 159 of the second moving portion 156, it is possible to prevent the second moving portion 156 from being separate from the second housing 151.

The second guide protrusion 154 is a rail that faces the second space 152 and protrudes from each of upper and lower sides of the second space 152 to be in an arc shape. The second guide protrusion 154 guides a rotation of the second moving portion 156 together with the second extending panel 159 by being stopped at a stepped recess portion that is provided to the second extending panel 159.

The second fastening gear 155 is a gear that is formed in an arc shape on each of the upper and lower sides of the second housing 151 together with the second guide protrusion 154.

The second moving portion 156 is disposed to be movably inward and outward relative to the second housing 151, and includes a second moving panel 157 on which the connecting hole 158 is formed. The second moving portion 156 according to example embodiments includes the second moving panel 157, the second extending panel 159, and a second moving gear 160.

The second moving panel 157 is provided in a shape of a plate shape that is disposed to vertically stand, and includes the connecting hole 158. The second extending panel 159 extends laterally from the second moving panel 157 and is inserted into the second housing 151. A groove portion in an arc shape is provided to the second extending panel 159, and a stopping groove portion into which the second guide protrusion 154 is inserted and thereby stopped is formed at the outer side of the groove portion in the arc shape.

The second moving gear 160 forms a gear in a circumferential direction along the side of the second extending panel 159, and the second fastening gear 155 is disposed on each of upper and lower sides of the second moving gear 160.

The connection coupling portion 161 is rotatably provided to the second moving panel 157, rotates together with the second moving portion 156, and includes a fastening protrusion 162 that protrudes through the connecting hole 158. A configuration and an operation state of the connection coupling portion 161 are identical to those of the coupling protruding portion 80 or the second connecting portion 100. Accordingly, a detailed description related thereto is omitted.

The third lock member 163 is rotatably provided to the second housing 151, and confines a movement of the second moving portion 156 through an operation of engaging into the side of the second moving portion 156 of which movement is completed. A configuration and an operation state of the third lock member 163 are identical to those of the first lock member 144. Accordingly, a further description related thereto is omitted.

The fourth lock member 164 is rotatably disposed on the side of the third lock member 163, moves to confine a rotation of the third lock member 163 after a locking operation of the third lock member 163 is completed, and confines unlocking of the third lock member 163. A configuration and an operation of the fourth lock member 164 are identical to those of the second lock member 147. Accordingly, a further description related thereto is omitted.

The vertical locking portion 170 is disposed on the upper side of the support frame 115, and has the same configuration and operation state to those of the coupling protruding portion 80 of the base frame portion 50.

Also, the standard connecting portion 180 to which the vertical locking portion 170 is connected has the same configuration and operation state to those of the coupling portion 70 of the base frame portion 50. Accordingly, a further description related thereto will be omitted.

As illustrated in FIGS. 27 through 29, the touring frame 200 may be provided in various shapes without departing from the technical spirit that the touring frame 200 is coupled to the base frame portion 50 and includes a support shape over which a hand or a foot of an operator to be hanged. The touring frame 200 includes a touring body 201, a gripping member 203, a first touring combining portion 210, and a second touring combining portion 220.

The touring body 201 is provided in a shape of a quadrilateral frame, and the gripping member 203 for forming a gripping hole is disposed on each of an upper side and a lower side of the touring body 201. Accordingly, when the touring frames 200 are vertically stacked, the touring frame 200 may be used for the operator to step up or hold up the foot with holding the gripping member 203, thereby enhancing the work efficiency.

The first touring combining portion 210 is disposed on one of both sides of the touring body 201, and the second touring combining portion 220 is disposed on another side thereof. The first touring combining portion 210 includes a first touring housing 212 configured to form an internal space, a control member 214 rotatably disposed at an outer side of the first touring housing 212, and a connecting ring 216 that is connected to the control member 214, rotates inside the first touring housing 212, and protrudes outward from the first touring housing 212.

The second touring combining portion 220 is disposed on the neighboring touring frame 200, and a pin member to be stopped by the connecting ring 216 is provided inside the second touring housing 222.

Hereinafter, an operation state of the display device 1 according to example embodiments will be described with reference to the accompanying drawings.

As illustrated in FIGS. 1 through 3, a plurality of modules each in which the image panel 10 and the control module 20 are coupled to the base frame portion 50 may be connected to one another. Four image panels 10 is attached to the base frame portion 50. Such the base frame portion 50 may be coupled to its neighboring base frame portion 50 by way of the first connecting portion 90, the second connecting portion 100, the coupling protruding portion 80, and the coupling portion 70.

As illustrated in FIGS. 5 and 6, when retracting the image panel 10 to the rear portion of the base frame portion 50, the image panel 10 moves through the first service space portion 68.

As illustrated in FIGS. 7 through 9, when retracting the control module 20 to the front portion of the base frame portion 50, the control module 20 is withdrawn retracted the second service space portion 69 that is formed by rotating the second mount connecting portion 64.

As illustrated in FIGS. 10 and 11, the image panel 10 is fastened to the base frame portion 50 using the first connecting member 30 and the second connecting member 40. As illustrated in FIG. 4, the image panel 10 may be fastened to the base frame portion 50 by separately disposing the panel fastening portion 19 on a rear side of the image panel 10.

As illustrated in FIG. 17, when connecting the first connecting portion 90 and the second connecting portion 100 to each other, the second coupling protrusion body 101 is positioned in front of the connecting hole 91. As illustrated in FIG. 18, the second coupling protrusion body 101 is inserted into the first connecting body 92.

As illustrated in FIG. 19, since the second stopping bead 102 is stopped by a step provided inward to an inlet of the first connecting body 92 by moving the second connection moving member 109 backward, a provisional coupling between the first connecting portion 90 and the second connecting portion 100 is performed. Since the second coupling protrusion body 101 moves backward together with the second stopping bead 102 by rotating the second coupling lever 10, a virtual pressure at which the second stopping bead 102 is stopped by the step provided inward to the inlet of the first connecting body 92 increases.

As illustrated in FIG. 20, the first connecting body 92 moves to be separate away from the second connecting body by also rotating the first coupling lever 97. Thus, the virtual pressure at which the second stopping bead 102 is stopped by the step provided inward to the inlet of the first connecting body 92 increases and a clamping force between the first connecting portion 90 and the second connecting portion 100 is enhanced.

As illustrated in FIGS. 23 through 26, when the standard frame portion 112 is coupled to its neighboring standard frame portion 112, the fastening protrusion 162 of the connection coupling portion 161 is inserted into the insertion hole 140 of the first moving panel 139 and thereby coupled thereto. Once a rotational angle is adjusted by rotating the first moving portion 138 and the second moving portion 156, a rotation of the first moving portion 138 and the second moving portion 156 is confined by rotating the first lock member 144 and the third lock member 163.

As illustrated in FIG. 29, the display device 1 may be employed as a module in which the touring frame 200 is coupled to the base frame portion 50 to which the image panel 10 is provided.

Alternatively, as illustrated in FIG. 30, the display device 1 may be employed as a module in which the standard frame portion 112 is coupled to the base frame portion 50 to which the image panel 10 is provided.

Alternatively, as illustrated in FIGS. 31 and 32, the display device 1 may be employed as a module in which the standard frame portion 112 and the touring frame 200 are coupled to the base frame portion 50 to which the image panel 10 is provided.

As described above, according to example embodiments, a plurality of image panels 10 is detachably disposed on the front portion of the base frame portion 50 and the control module 20 is detachably disposed on the rear portion of the base frame portion 50, based on the base frame portion 50. Accordingly, it is possible to reduce an amount of time used to install and de-install a device. Further, a double-coupling between the first connecting member 30 provided to the base frame portion 50 and the second connecting member 40 provided to the image panel 10 is performed through a magnetic force and a mechanical structure. Accordingly, an operation of attaching and detaching the plurality of image panels 10 may be easily performed, thereby reducing an operation time. Also, since the image panel 10 is easily movable to the front portion and the rear portion of the base frame portion 50 through the first service space portion 68 diagonally formed in the base frame portion 50, it is possible to save a time and cost used for a maintenance and repair. In addition, since the second service space portion 69 is formed inside the base frame portion 50 by rotating the second mount connecting portion 64 and the control module 20 is easily movable to the front portion and the rear portion of the base frame portion 50 through the second service space portion 69, it is possible to save a time and cost used for a maintenance and repair. Further, since the fastening protrusion 162 of the second tilting portion 150 is inserted into the insertion hole 140 of its neighboring first tilting portion 130 and accordingly, the second tilting portion 150 is coupled to the first tilting portion 130, a coupling operation between the neighboring standard frame portions 112 may be easily performed. Also, in a state in which the first tilting portion 130 and the second tilting portion 150 are connected to each other, an angle may be easily adjusted by rotating the first moving portion 138 and the second moving portion 156, thereby saving an operation time and cost.

Although a few example embodiments of the present disclosure have been shown and described, the present disclosure is not limited to the described example embodiments. Instead, it would be appreciated by those skilled in the art that changes may be made to these embodiments without departing from the principles and spirit of the invention, the scope of which is defined by the claims and their equivalents.

What is claimed is:

1. A display device comprising:
an image panel on which a plurality of light emitting elements are arranged in a planar shape;
a control module connected to the image panel and supplying a control signal and a power to the image panel; and
a base frame portion on one side of which the image panel is detachably disposed and on another side of which the control module is detachably disposed.

2. The display device of claim 1, wherein the image panel is provided in a quadrilateral shape and is coupled to the base frame portion through a magnetic force.

3. The display device of claim 1, wherein the control module comprises:
a control body fastening to the other side of the base frame portion;
a connecting terminal protruding outward from the control body; and
an input terminal connected to a fixed terminal that is provided to the base frame portion, and supplying the control signal and the power to the image panel.

4. The display device of claim 1, wherein the base frame portion comprises:
a base body forming a frame in a quadrilateral shape;
a detachable mounting portion provided inside the base body, and to enable detachment of the control module; and
an inner connecting portion connecting the detachable mounting portion to the base body, and to fasten the detachable mounting portion inside the base body.

5. The display device of claim 4, wherein the image panel moves to a first service space portion formed between the inner connecting portion and the base body.

6. The display device of claim 4, wherein the inner connecting portion extends upward and downward and leftward and rightward from the detachable mounting portion and is connected to the base body, and the first service space portion is formed in a diagonal direction of the base frame portion.

7. The display device of claim 4, wherein the base frame portion comprises:
a coupling portion provided on one of an upper side and a lower side of the base body and including a fastening hole; and
a coupling protruding portion disposed at a position opposite to a position of the coupling portion in the base body, and protruding outward from the base body, and to insert into a coupling portion of a neighboring base frame portion and thereby fasten thereto.

8. The display device of claim 7, wherein the coupling protruding portion comprises:
a coupling protrusion body internally provided with an operation space and of which one side is inserted into the fastening hole;
a stopping bead provided on one side of the coupling protrusion body, and disposed to be movable inward and outward relative to the coupling protrusion body;
an inner moving member moving in a lengthwise direction along the inner side of the coupling protrusion body, and including an inner groove portion that receives the stopping bead; and
an inner returning member disposed between the inner moving member and the coupling protrusion body, and elastically pressurizing the inner moving member to be separate away from the stopping bead.

9. The display device of claim 8, wherein the coupling protruding portion comprises:
a coupling lever rotatably disposed at the outer side of the coupling protrusion body and including a protrusion in a cam shape on its side, and making the coupling protrusion body move backward in contact with a mounting frame that supports the coupling protrusion body through a rotating motion; and
a support connecting shaft disposed to pass through the coupling lever, the coupling protrusion body, and the inner moving member.

10. The display device of claim 4, wherein the base frame portion comprises:
a first connecting portion disposed on one of a left side and a right side of the base body and including a connecting hole; and
a second connecting portion disposed at a position opposite to a position of the first connecting portion, and protruding outward from the base body, and to insert into a first connecting portion of a neighboring base frame portion and thereby fasten thereto.

11. The display device of claim 10, wherein the first connecting portion comprises:
a first connecting body including an operation space that communicates with the connecting hole;
a first inner moving member moving in a lengthwise direction along an inner side of the first connecting body, and including a side hole portion through which a bead shape is received; and
a first inner returning member elastically pressurizing the first inner moving member to be separate away from the connecting hole.

12. The display device of claim 11, wherein the second connecting portion comprises:
a second coupling protrusion body internally provided with an operation space and of which one side is inserted into the inner side of the first connecting body;
a second stopping bead provided on one side of the second coupling protrusion body, disposed to be movable inward and outward relative to the second coupling protrusion body, and inserted into the side hole portion and thereby stopped therein;
a second inner moving member moving in a lengthwise direction along the inner side of the second coupling protrusion body, and including a second inner groove portion that receives the second stopping bead; and
a second inner returning member disposed between the second inner moving member and the second coupling protrusion body, and elastically pressurizing the second inner moving member to be separate away from the second stopping bead.

13. The display device of claim 12, wherein the second connecting portion comprises:
a second coupling lever rotatably disposed at the outer side of the second coupling protrusion body, including a protrusion in a cam shape on its side, and making the second coupling protrusion body move backward in contact with a second mounting frame that supports the second coupling protrusion body through a rotating motion; and
a second support connecting shaft disposed to pass through the second coupling lever, the second coupling protrusion body, and the second inner moving member.

14. The display device of claim 1, further comprising:
a touring frame coupled to the base frame portion and including a supporting shape over which a hand or a foot of an operator is to be hung,
wherein the touring frame comprises:
a touring body provided in a quadrilateral shape; and
a gripping member forming a gripping hole on each of an upper side and a lower side of the touring body.

15. The display device of claim 1, further comprising
a standard frame portion coupled to the base frame portion and including a tilting portion that adjusts a coupling angle on its both sides,
wherein the standard frame portion comprises:
a support frame forming a framework in a quadrilateral shape;
a first tilting portion disposed on one of a left side and a right side of the support frame, including an insertion hole, and adjusting an angle of a portion to be coupled; and
a second tilting portion disposed at a position opposite to a position of the first tilting portion, protruding outward from the support frame, and coupled to a neighboring first tilting portion, and adjusting an angle of a portion to be coupled.

16. The display device of claim 15, wherein the first tilting portion comprises:
a first housing forming a first space inside the support frame;
a first moving portion disposed to be movable inward and outward relative to the first housing, and including a first moving panel on which the insertion hole is formed;
a first lock member rotatably provided to the first housing, and confining a movement of the first moving portion through an operation of engaging into the side of the first moving portion of which movement is completed; and
a second lock member rotatably disposed on the side of the first lock member, moving to confine a rotation of the first lock member after a locking operation of the first lock member is completed and to confine unlocking of the first lock member, and
the second tilting portion comprises:
a second housing forming a second space inside the support frame;
a second moving portion disposed to be movable inward and outward relative to the second housing, and including a second moving panel on which a connecting hole is formed;
a connection coupling portion provided to the second moving panel, rotating together with the second moving portion, and including a fastening protrusion that protrudes through the connecting hole;
a third lock member rotatably provided to the second housing, and confining a movement of the second moving portion through an operation of engaging into the side of the second moving portion of which movement is completed; and
a fourth lock member rotatably disposed on the side of the third lock member, moving to confine a rotation of the third lock member after a locking operation of the third lock member is completed and to confine unlocking of the third lock member.

17. The display device of claim 16, wherein the first housing comprises:
a first support protrusion passing through the first moving portion;
a first guide protrusion disposed on each of both sides of the first support protrusion, and guiding a rotation of the first moving portion by being stopped at an outer side of the first moving portion; and
a first fastening gear forming a step in relation to the first guide protrusion, disposed on each of an upper side and a lower side of the first moving portion, and forming a gear in a circumferential direction, and
the first moving portion comprises:
a first extending panel extending laterally from the first moving panel and to insert into the first housing; and
a first moving gear forming a gear in a circumferential direction along the side of the first extending panel.

18. The display device of claim 17, wherein the first lock member comprises:
a first lock body facing the first moving gear, and rotatably disposed inside the first housing; and
a first lock gear forming a gear along the side of the first lock body, and to engage into the first moving gear and the first fastening gear through a rotation of the first lock body, and
the second lock member comprises:
a second lock body facing the first lock body, and rotatably disposed inside the first housing; and
a lock protrusion member protruding from the side of the second lock body in a cam shape, and to confine the rotation of the first lock body in contact with the first lock body through a rotation of the second lock body.

19. The display device of claim 16, wherein the second housing comprises:
a second support protrusion passing through the second moving portion;
a second guide protrusion disposed on each of both sides of the second support protrusion, and guiding a rotation of the second moving portion by being stopped at an outer side of the second moving portion; and
a second fastening gear forming a step in relation to the second guide protrusion, disposed on each of an upper side and a lower side of the second moving portion, and forming a gear in a circumferential direction, and
the second moving portion comprises:
a second extending panel extending laterally from the second moving panel and to insert into the second housing; and
a second moving gear forming a gear in a circumferential direction along the side of the second extending panel.

20. The display device of claim 1, further comprising:
a first connecting member fastening to the base frame portion, and having a magnetic force;
a second connecting member facing the first connecting member, to fasten to the image panel, and to fasten to the first connecting member through the magnetic force,
wherein the first connecting member comprises:
a first connecting housing fastening to the base frame portion;
a first bonding member fastening to the first connecting housing and having a magnetic force; and
a first stopper protruding along the periphery of the first bonding member and to be fastened by being stopped by the second connecting member,
the first stopper comprises:
a first boundary member protruding outward from the first connecting housing to be in a ring shape; and
a first hook member separated from the first boundary member and to protrude outward from the first connecting housing to be in a hook shape,
the second connecting member comprises:
a second connecting housing fastening to the image panel;
a second bonding member fastening to the second connecting housing, and molded using iron or magnet as a material; and
a second stopper protruding along the periphery of the second bonding member, and to be fastened by being stopped by the first stopper, and
the second stopper comprises:
a second boundary member protruding outward from the second connecting housing to be in a ring shape and to make the first hook member be stopped at its side; and
a second hook member protruding inward from the second boundary member and to grip the second bonding member.
